(19) United States
(12) Patent Application Publication
(10) Pub. No.: US 2008/0230885 A1
(43) Pub. Date: Sep. 25, 2008

(54) CHIP HERMETIC PACKAGE DEVICE AND METHOD FOR PRODUCING THE SAME

(75) Inventors: Meng-jen Wang, Kaohsiung City (TW); Kuo-pin Yang, Kaohsiung City (TW); Sheng-yang Peng, Kaohsiung City (TW)

Correspondence Address: MADSON & AUSTIN, 15 WEST SOUTH TEMPLE, SUITE 900, SALT LAKE CITY, UT, 84101, US

(73) Assignee: Advanced Semiconductor Engineering, Inc., Kaohsiung (TW)

(21) Appl. No.: 12/053,192

(22) Filed: Mar. 21, 2008

(30) Foreign Application Priority Data
Mar. 22, 2007 (TW) 096109962

(51) Int. Cl. H01L 23/02; H01L 21/00

(52) U.S. Cl. 257/678; 438/124; 257/E21.001; 257/E23.18

(57) ABSTRACT

A chip hermetic package device includes a substrate, a chip, a hermetic lid, a hermetic material and a post. The height of the post is larger than the thickness of the hermetic material. A method for producing a chip hermetic package includes the steps of: mounting the chip on the substrate; disposing the post and the hermetic material between the substrate and the hermetic lid; disposing the hermetic lid on the substrate to form a chamber, the post supporting the hermetic lid on the substrate to form an air passage; and performing a sealing step in an atmosphere of inert gas. The present invention utilizes the post to form the air passage between the substrate and the hermetic lid. Therefore, only is the sealing step performed in the atmosphere of nitrogen, and present invention needs a reduced number of equipment. Therefore, the present invention has a low cost, simplifies the packaging process and improves efficiency.

### BACKGROUND OF THE INVENTION

1. Field of the Invention

The present invention generally relates to a hermetic package device and method for producing the same, and particularly relates to a chip hermetic package device and method for producing the same.

2. Description of Prior Art

As shown in FIG. 1, a conventional method for producing a chip hermetic package includes a manufacturing step 11, a lid-mounting step 12, and a sealing step 13.

Referring to FIG. 2, the manufacturing step 11 is provided for manufacturing a substrate 21 and a sealing cover or a lid 22. The substrate 21 couples to the sealing cover 22 so as to form an enclosed cavity 20 therebetween. Next, a chip 23 is mounted to the substrate 21. A number of wires 24 electrically connect the chip 23 with the substrate 21. The sealing cover 22 has an annular ring of solder 25 disposed on the bottom thereof.

The lid-mounting step 12 is performed in an atmosphere of nitrogen. In the lid- mounting step 12, the sealing cover 22 is disposed on the substrate 21 so as to cover the chip 23 and then the sealing step 13 is conducted thereafter. The sealing step 13 is also performed in the atmosphere of nitrogen. Finally, the substrate 21 and the sealing cover 22 are heated so as to melt the annular ring of solder 25 by which the sealing cover 22 and the substrate 21 are held together.

The method for producing the chip hermetic package is usually performed in clean atmospheres. After coupling the sealing cover 22 to the substrate 21, the enclosed cavity 20 is evacuated for exhausting the air therein and subsequently nitrogen gas is refilled in the cavity 20 such that the oxygen content in the cavity 20 is less than 50 ppm prior to performing the sealing step 13.

Because the annular ring of solder 25 tends to tightly hold the sealing cover 22 on the substrate 21 when the sealing cover 22 is coupled to the substrate 21, the air in the enclosed cavity 20 may not be removed efficiently by evacuating process and thus nitrogen gas may not be adequately refilled in the cavity 20, which adversely affects the packaging process. To address this problem, in the conventional method, the lid-mounting step 12 and the sealing step 13 are both performed in atmosphere of nitrogen to ensure a good package. Consequently, additional nitrogen cabinets have to be employed. Accordingly, the conventional method expands the application scope of nitrogen gas, which results in a complicated package process and a high cost.

### SUMMARY OF THE INVENTION

The object of the present invention is to provide a chip hermetic package device and method for producing the same, which is capable of reducing the manufacturing cost, simplifying package process and has a high efficiency.

A method for producing a chip hermetic package in accordance with the present invention includes the steps of: providing a substrate; mounting a chip on the substrate; providing a hermetic lid; disposing a post and a hermetic material between the substrate and the hermetic lid, wherein the height of the post is larger than the thickness of the hermetic material; disposing the hermetic lid on the substrate to form a chamber for containing the chip, the post supporting the hermetic lid on the substrate so as to form an air passage between the hermetic lid and the substrate; and performing a sealing step in an atmosphere of inert gas, heating the hermetic material to hold the substrate and the hermetic lid together by melted hermetic material, whereby the chamber becomes an enclosed space.

A chip hermetic package device in accordance with the present invention includes a substrate, a chip mounted on the substrate, a hermetic lid disposed on the substrate, a hermetic material and at least one post. The hermetic lid couples to the substrate to define a chamber for receiving the chip. The hermetic material and the at least one post are disposed between the substrate and the hermetic lid.

The chip hermetic package device and method for producing the same utilizes the post supporting the hermetic lid on the substrate, thereby forming the air passage between the substrate and the hermetic lid. Therefore, original air in the chamber can be easily exhausted through the air passage. That is to say, the present invention can easily control gas composition in the chamber by use of the air passage. The step of placing the hermetic lid on the substrate need not employ the atmosphere of nitrogen. Only is the sealing step performed in the atmosphere of nitrogen, and thus the present invention uses a reduced number of equipment. Therefore, the present invention simplifies packaging process and improves efficiency.

### BRIEF DESCRIPTION OF THE DRAWINGS

The present invention may best be understood through the following description with reference to the accompanying drawings, in which:

FIG. 1 illustrates a flowchart of a conventional method for producing a chip hermetic package method;

FIG. 2 is a schematic view of FIG. 1, sequentially illustrating the packaging process of the conventional method;

FIG. 3 is an exploded, perspective view of a chip hermetic package device according to a first preferred embodiment of the present invention;

FIG. 4 is a sectional view of FIG. 3, wherein a hermetic lid is disposed on a substrate;

FIG. 5 is an exploded, perspective view of a chip hermetic package device according to a second preferred embodiment of the present invention;

FIG. 6 is a sectional view of FIG. 5, wherein a hermetic lid is disposed on a substrate;

FIG. 7 is an exploded, perspective view of a chip hermetic package device according to a third preferred embodiment of the present invention;

FIG. 8 is an exploded, perspective view of a chip hermetic package device according to a fourth preferred embodiment of the present invention;

FIG. 9 is an exploded, perspective view of a chip hermetic package device according to a fifth preferred embodiment of the present invention;

FIG. 10 is an exploded, perspective view of a chip hermetic package device according to a sixth preferred embodiment of the present invention;

FIG. 11 illustrates a flowchart of a method for producing a chip hermetic package according to the first preferred embodiment of the present invention;

FIG. 12 is a schematic view of FIG. 11, sequentially illustrating a packaging process of the method for producing a chip hermetic package according to the first preferred embodiment of the present invention;

FIG. 13 is a schematic view, sequentially illustrating a package process of the method for producing a chip hermetic package according to the second preferred embodiment of the present invention; and

FIG. 14 is a schematic view, sequentially illustrating a package process of the method for producing a chip hermetic package according to the third preferred embodiment of the present invention.

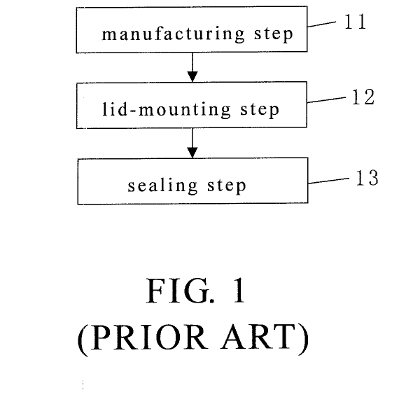

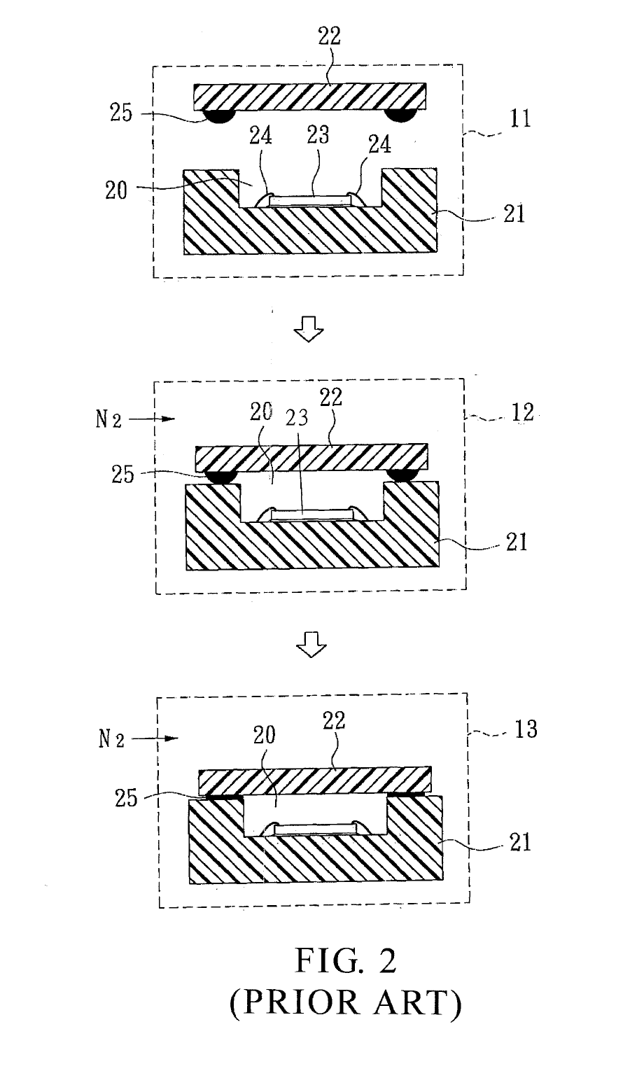

### DETAILED DESCRIPTION OF THE INVENTION

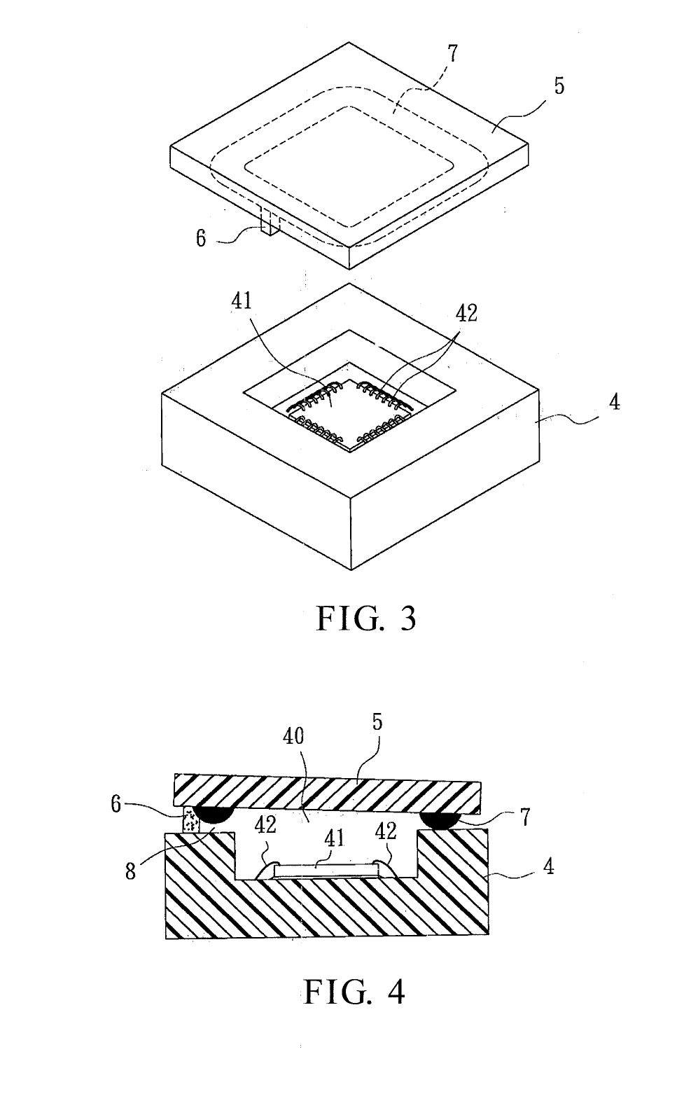

Referring to FIGS. 3 and 4, a chip hermetic package device in accordance with a first preferred embodiment of the present invention includes a substrate 4, a hermetic lid 5, an annular hermetic material 7 and a post 6.

The substrate 4 couples to the hermetic lid 5 to together define a chamber 40 in which a chip 41 is received. The chip 41 is mounted on the substrate 4. A plurality of wires 42 are provided to electrically connect the substrate 4 and the chip 41.

The annular hermetic material 7 and the post 6 are both disposed on a bottom surface of the hermetic lid 5. The hermetic material 7 is in an annular shape corresponding to that of the top of the substrate 4. When the hermetic lid 5 is disposed on the substrate 4, the post 6 and the hermetic material 7 are sandwiched between the substrate 4 and the hermetic lid 5. The height of the post 6 is larger than the thickness of the hermetic material 7 to incline the hermetic lid 5 on the substrate 4 such that an air passage 8 is formed between the substrate 4 and the tilted hermetic lid 5 for communicating the chamber 40 with outer environment.

In the first preferred embodiment, the post 6 is adjoined to the hermetic material 7 and is made of the same material as the hermetic material 7, such as welding material. Alternatively, the post 6 may be disposed distant from the hermetic material 7, and may be made of different material from that of the hermetic material 7. If a different material is used, the post 6 is preferably made of a soft material, such as a polymeric material.

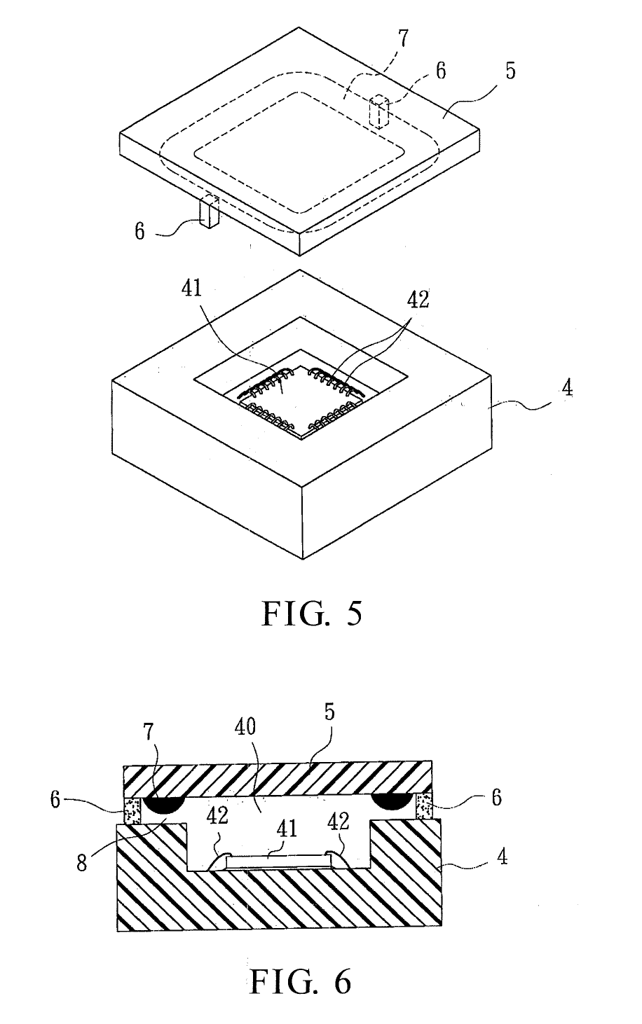

Referring to FIGS. 5 and 6, a chip hermetic package device in accordance with a second preferred embodiment of the present invention is substantially similar to that of the first preferred embodiment, except that the hermetic lid 5 of the second embodiment has a pair of posts 6 symmetrically disposed on opposite sides of the bottom surface thereof. The posts 6 individually stand beside the hermetic material 7 and are made of the same material as that of the hermetic material 7. Alternatively, the material of the posts 6 may be different from that of the hermetic material 7. Three or more posts 6 may be employed in the second embodiment and may be symmetrically/asymmetrically disposed on the bottom of the hermetic lid 5 as long as the air passage 8 can be formed between the substrate 4 and the hermetic lid 5.

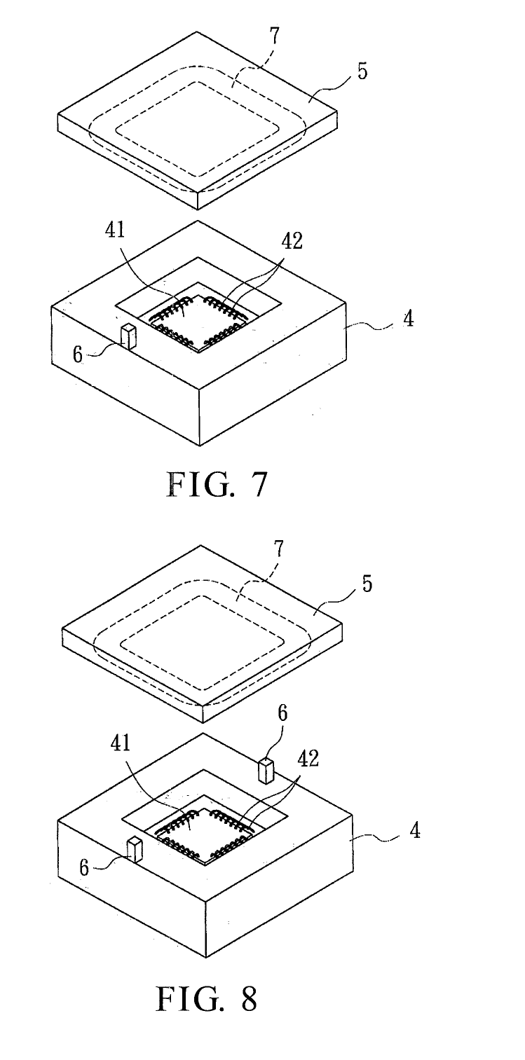

Referring to FIG. 7, a chip hermetic package device in accordance with a third preferred embodiment of the present invention is substantially similar to that of the first preferred embodiment, except that the post 6 is disposed on the top of the substrate 4 rather than on the bottom of the hermetic lid 5.

Referring to FIG. 8, a chip hermetic package device in accordance with a fourth preferred embodiment of the present invention is substantially similar to that of the third preferred embodiment, except that a pair of posts 6 are symmetrically disposed on opposite sides of the top of the substrate 4.

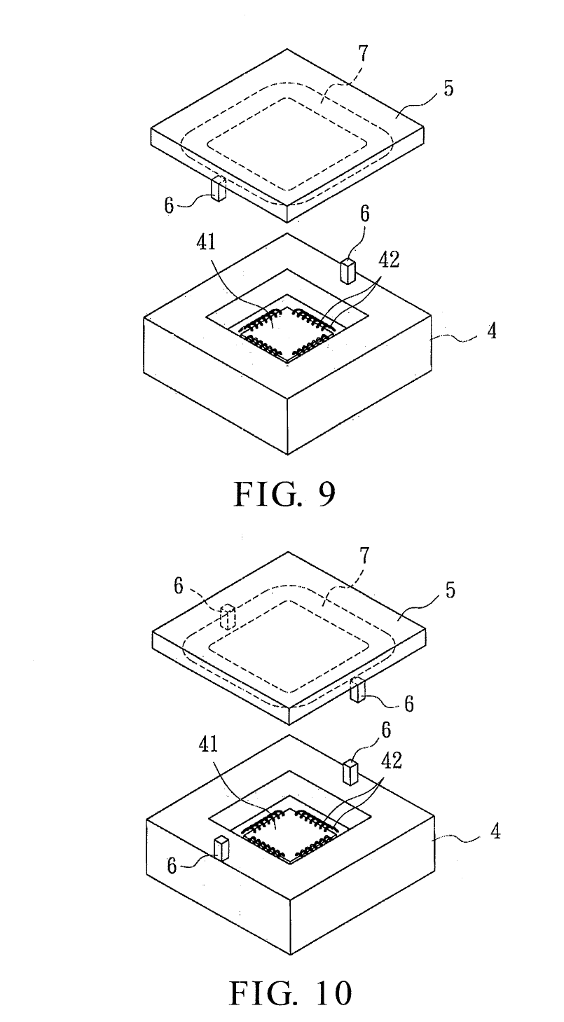

Referring to FIG. 9, a chip hermetic package device in accordance with a fifth preferred embodiment of the present invention is substantially similar to that of the first preferred embodiment, except that a pair of posts 6 are respectively disposed on the top of the substrate 4 and the bottom of the hermetic lid 5 and are opposite to each other when the hermetic lid 5 is placed on the substrate 4.

Referring to FIG. 10, a chip hermetic package device in accordance with a sixth preferred embodiment of the present invention is substantially similar to that of the fifth preferred embodiment, except that two pairs of posts 6 are employed in the sixth embodiment, wherein one pair of the posts 6 are symmetrically disposed on opposite sides of the top of the substrate 4, and the other pair of the posts 6 are symmetrically disposed on the opposite sides of the bottom surface of the hermetic lid 5. The posts 6 respectively stand on fours sides of the hermetic lid 5 and the substrate 4 when the hermetic lid 5 is placed on the substrate 4.

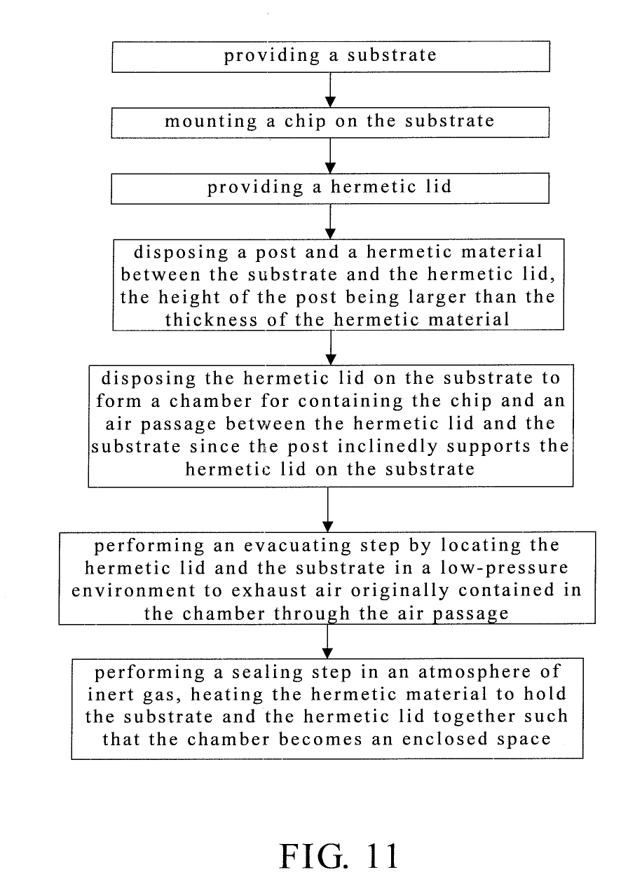

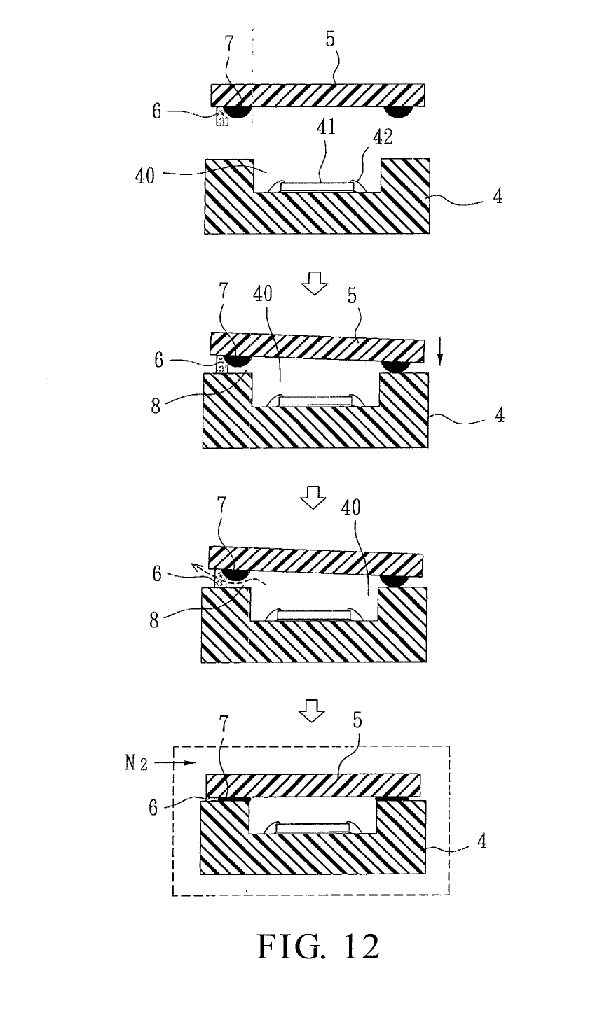

Referring to FIGS. 11 and 12, the method for producing a chip hermetic package according to the first embodiment of the present invention includes following steps of:
a) providing a substrate 4;
b) mounting a chip 41 on the substrate 4;
c) providing a hermetic lid 5;
d) disposing a post 6 and a hermetic material 7 between the substrate 4 and the hermetic lid 5. The height of post 6 is larger than the thickness of the hermetic material 7. In the first preferred embodiment, the post 6 and the hermetic material 7 are both disposed on the bottom surface of the hermetic lid 5. The hermetic material 7 is disposed on the hermetic lid 5 and is in an annular shape corresponding to that of the top of the substrate 4;
e) disposing the hermetic lid 5 on the substrate 4 to form a chamber 40 for containing the chip 41 and an air passage 8 between the hermetic lid 5 and the substrate 4. In the first preferred embodiment, since the post 6 projects away from the hermetic lid 5 a further distance than the hermetic material 7, the post 6 inclinedly supports the hermetic lid 5 on the substrate 4 so as to form the air passage 8;
f) performing an evacuating step. The hermetic lid 5 and the substrate 4 are located in a low-pressure environment so as to exhaust air originally contained in the chamber 40 (as indicated by dashed line in FIG. 12). In the embodiment, one air exhausting cabinet (not shown) is employed to exhaust the air originally contained in the chamber 40. It should be noted that if original oxygen content in the chamber 40 is lower than a predetermined value, the evacuating step can be omitted and a sealing step can be performed directly; and
g) performing a sealing step in an atmosphere of inert gas, such as nitrogen (N2), argon, neon etc., to exhaust the remaining oxygen in the chamber 40, thereby preventing the wires 42 from oxidation and consequently assuring reliable signal transmission between electronic elements. By heating the hermetic material 7, the substrate 4 and the hermetic lid 5 are held together by melted hermetic material 7 such that the chamber 40 becomes an enclosed space.

Additionally, in the sealing step, the hermetic lid 5 may be firstly pressed downwardly to squash the post 6 such that the post 6 has the same thickness as that of the hermetic material 7. As a result, the inclined hermetic lid 5 is laid flat on the substrate 4 and completely seals the substrate 4 by the melted hermetic material 7. Alternatively, rather than pressing the hermetic lid 5 downwardly, the post 6 can be heated to soften so as to allow the hermetic lid 5 to lay flat on the substrate 4.

In the first embodiment, the post 6 and the hermetic material 7 may be made of the same material, such as welding material. Alternatively, the post 6 may be made of a different material from that of the hermetic material 7. If applying the same material, the post 6 and the hermetic material 7 can melt simultaneously during heating so as to get downwardly the hermetic material 7 to completely contact the substrate 4 and hold the hermetic lid 5 and the substrate 4 together. If applying different materials, the post 6 is preferably made of a soft material and which can be deformed under pressure, whereby the hermetic material 7 can completely contact the substrate 4 to hold the hermetic lid 5 and the substrate 4 together.

In the first embodiment, the post 6 and the hermetic material 7 contact with each other. The post 6 and the hermetic material 7 are fused together and both can function as bonding material. Alternatively, the post 6 can be spaced from the hermetic material 7 and the spacing structure has similar function to the abovementioned contacting structure.

As described above, in the first embodiment of the present invention, the post 6 is disposed on the hermetic lid 5. When the hermetic lid 5 is disposed on the substrate 4, the hermetic material 7 cannot completely contact the substrate 4, thereby forming the air passage 8 to ensure exhaustion of the air in the chamber 40 in the evacuating step. Therefore, the step of placing the hermetic lid 5 on the substrate 4 need not employ the atmosphere of nitrogen. Consequently, in the present invention, only is the sealing step performed in the atmosphere of nitrogen. This reduces the number of equipments employed in the present method for producing the chip hermetic package, such as cabinets for preserving nitrogen, and also cuts the manufacturing cost. Since the number of equipment is reduced, the present invention has a simple packaging process and a high efficiency.

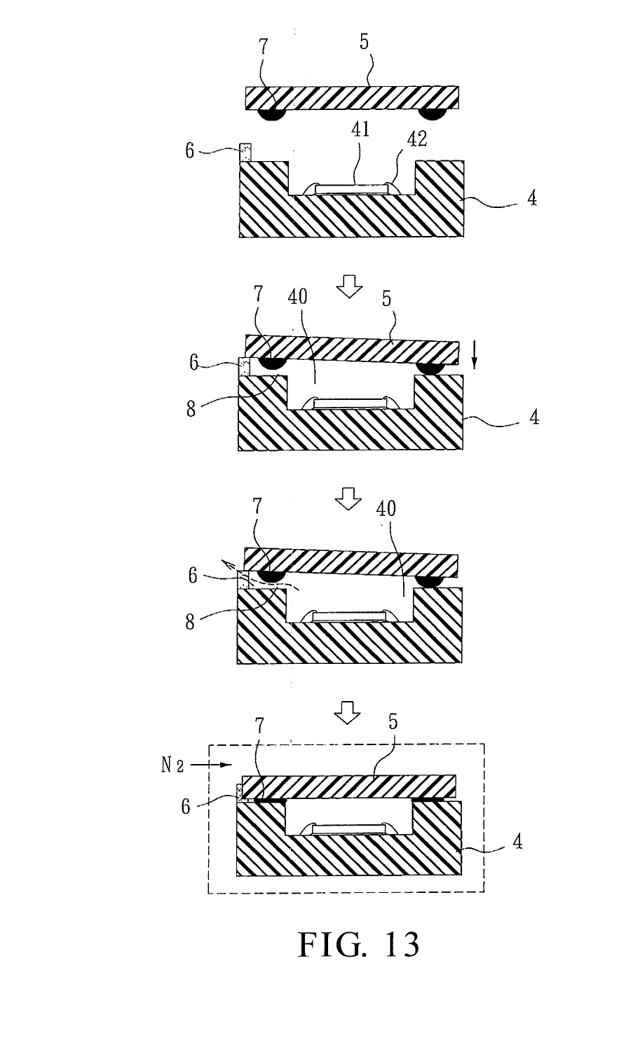

Referring to FIG. 13, the method for producing a chip hermetic package according to a second embodiment of the present invention is substantially similar to that of the first embodiment except that the post 6 is located at a different position. In the second embodiment, the post 6 is located on the top of the substrate 4. The post 6 is located approximate to the hermetic material 7 when the hermetic lid 5 is placed on the substrate 4. The post 6 may be made of the same material as that of the hermetic material 7.

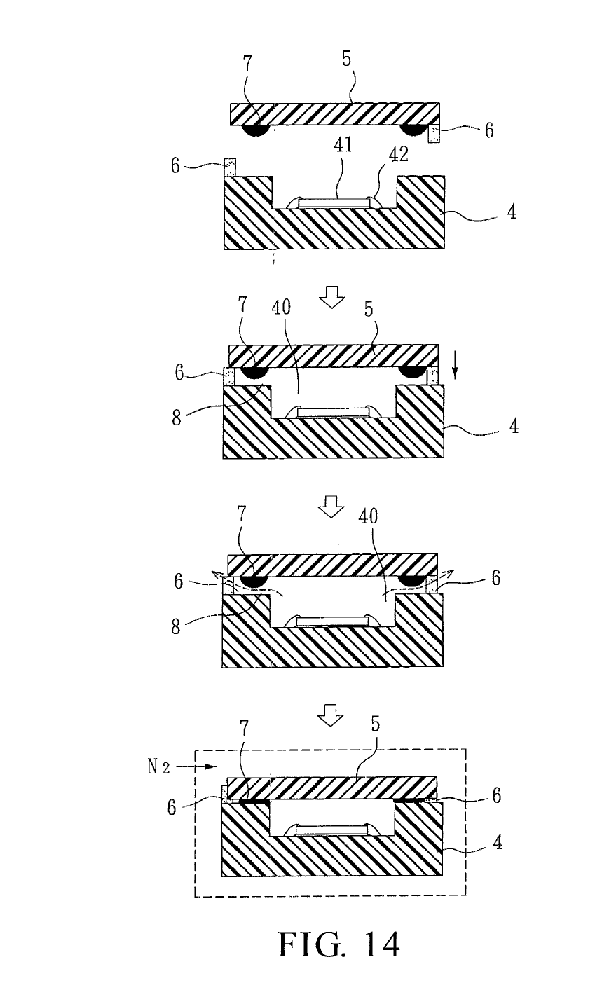

Referring to FIG. 14, the method for producing a chip hermetic package according to a third embodiment of the present invention is substantially similar to that of the first embodiment except that a pair of posts 6 are respectively disposed on the top of the substrate 4 and the bottom of the hermetic lid 5 and are opposite to each other. The pair of posts 6 are made of different types of material from that of the hermetic material 7.

Therefore, a chip hermetic package device and method for producing the same according to the present invention provide at least one post 6 between the substrate 4 and the hermetic lid 5, such that the hermetic material 7 cannot completely contact the substrate 4 when the hermetic lid 5 is disposed on the substrate 4, and thus an air passage 8 is formed between the substrate 4 and the hermetic lid 5. Therefore, original air in the chamber 40 can be easily exhausted through the air passage 8. That is to say, the present invention can easily control gas composition in the chamber 40 by use of the air passage 8. Nitrogen is refilled in the chamber 40 in the sealing step. The step of placing the hermetic lid 5 on the substrate 4 need not employ the atmosphere of nitrogen, thereby reducing the number of equipments used in the present method for producing the chip hermetic package. Therefore, the present invention simplifies packaging process and improves efficiency.

It is to be understood, however, that even though numerous characteristics and advantages of the present invention have been set forth in the foregoing description, together with details of the structure and function of the invention, the disclosure is illustrative only, and changes may be made in detail, especially in matters of shape, size, and arrangement of parts within the principles of the invention to the full extent indicated by the broad general meaning of the terms in which the appended claims are expressed.

What is claimed is:

1. A method for producing a chip hermetic package comprising the steps of:
providing a substrate;
mounting a chip on the substrate;
providing a hermetic lid;
disposing a post and a hermetic material between the substrate and the hermetic lid, the height of the post being larger than the thickness of the hermetic material;
disposing the hermetic lid on the substrate to form a chamber for containing the chip, the post supporting the hermetic lid on the substrate in an inclined manner to form an air passage between the hermetic lid and the substrate; and
performing a sealing step in an atmosphere of inert gas, the sealing step comprising heating the hermetic material to hold the substrate and the hermetic lid together by melted hermetic material, whereby the chamber becomes an enclosed space.

2. The method of a claim 1, wherein the post is disposed on the top of the substrate.

3. The method of a claim 1, wherein the post is disposed on the bottom of the hermetic lid.

4. The method of a claim 1, further comprising an evacuating step before the sealing step, the evacuating step including locating the substrate and the hermetic lid in a low-pressure environment so as to exhaust air originally contained in the chamber through the air passage.

5. The method of a claim 1, wherein the post is made of the same material as that of the hermetic material.

6. The method of a claim 1, wherein the post is made of different material from that of the hermetic material, the different material being a soft material.

7. The method of a claim 6, wherein the sealing step comprises first pressing downwardly the hermetic lid to squash the post so that the post has the same thickness as that of the hermetic material.

8. The method of a claim 1, wherein the post has a melting point less than or equal to that of the hermetic material.

9. The method of a claim 1, wherein the post has a melting point higher than that of the hermetic material.

10. The method of a claim 1, wherein the post contacts with the hermetic material.

11. The method of a claim 1, wherein the post is located approximate to the hermetic material.

12. A chip hermetic package device comprising:
a substrate;
a chip mounted on the substrate;
a hermetic lid disposed on the substrate and coupled to the substrate to define a chamber for receiving the chip; and
a hermetic material and at least one post disposed between the substrate and the hermetic lid.

13. The chip hermetic package device of claim 12, wherein the at least one post is made of the same material as that of the hermetic material.

14. The chip hermetic package device of claim 12, wherein the at least one post is made of different material from that of the hermetic material.

15. The chip hermetic package device of claim 12, wherein the at least one post contacts with the hermetic material.

16. The chip hermetic package device of claim 12, wherein the at least one post is located approximate to the hermetic material.

17. The chip hermetic package device of claim 12, wherein the post is made of the same material as that of the hermetic material.

18. The chip hermetic package device of claim 12, wherein the post is made of different material from that of the hermetic material.

19. The chip hermetic package device of claim 12, wherein the post contacts with the hermetic material.

20. The chip hermetic package device of claim 12, wherein the post is located approximate to the hermetic material.
